(19) United States
(12) Patent Application Publication
(10) Pub. No.: US 2008/0316693 A1
(43) Pub. Date: Dec. 25, 2008

(54) HOUSING WITH ROTATABLE COVER ASSEMBLY

(75) Inventors: HUA-TANG LI, Shenzhen (CN); YUN-LUNG CHEN, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 11/836,801

(22) Filed: Aug. 10, 2007

(30) Foreign Application Priority Data
Jun. 20, 2007 (CN) 200720200496.2

(51) Int. Cl. H05K 5/02

(52) U.S. Cl. 361/683; 361/727

(57) ABSTRACT

A housing assembly includes a housing (3), a pair of connecting arms (51), and a cover (1). The housing includes a front opening, a side wall (31), a top wall and a bottom wall positioning at opposite sides of the side wall. The top wall and bottom wall each has a slot (38) defined therein. Each connecting arm (51) has a first end slidably engaged in the slot, and an opposite second end. The cover (1) is pivotally connected to the second ends of the connecting arms for covering the front opening of the housing.

### BACKGROUND

1. Field of the Invention

The present invention relates to a housing with rotatable cover assembly, and more particularly to a housing for an I/O connector of a computer.

2. Description of Related Art

Computer housing usually has a plurality of I/O connectors (e.g., USB connector, PS2 connector, microphone connector, etc.) at a back side thereof for data communicating with other electronic components (e.g., movable hard disk, USB storage device, microphone, etc.). The computer housing typically includes one or more covers to cover the I/O connectors when one or more I/O connectors are out of use.

For both functional and aesthetic reasons, such covers should fit the I/O connectors. The I/O connectors and the cover reduce the amount of dust and dirt that can enter the computer housing when the cover is closed, and also provides a more pleasing appearance. Additionally, the covers minimize the risk of accidental damage to the I/O connectors.

Some traditional I/O connector covers are rotatably attached to the computer housing. The maximum rotating range of covers is usually no more than 90 degree. This kind of covers is inconvenient when connected electronic components have large-sized connector.

What is needed, therefore, is housing with a rotatable cover assembly for an I/O connector, especially for a housing with rotatable cover assembly which has a simple structure and can be expediently used.

### SUMMARY

A housing assembly includes a housing, a pair of connecting arms, and a cover. The housing includes a front opening, a side wall, a top wall and a bottom wall positioning at opposite sides of the side wall. The top wall and bottom wall each has a slot defined therein. Each connecting arm has a first end slidably engaged in the slot, and an opposite second end. The cover is pivotally connected to the second ends of the connecting arms for covering the front opening of the housing.

Other advantages and novel features of the present invention will become more apparent from the following detailed description of a preferred embodiment when taken in conjunction with the accompanying drawings, in which:

### BRIEF DESCRIPTION OF THE DRAWINGS

FIG. 1 is a partially exploded, isometric view of a housing with rotatable cover assembly of an electronic housing according to a preferred embodiment of the present invention, the housing including a cover, and a pair of connecting arms;

FIG. 2 is an enlarged, isometric view of one of the connecting arms with two hinge pins of FIG. 1;

FIG. 3 is an isometric, assembled view of FIG. 1, but shown from a front aspect; and

FIG. 4 is similar to FIG. 3, but the cover is in an opened position.

### DETAILED DESCRIPTION OF THE EMBODIMENT

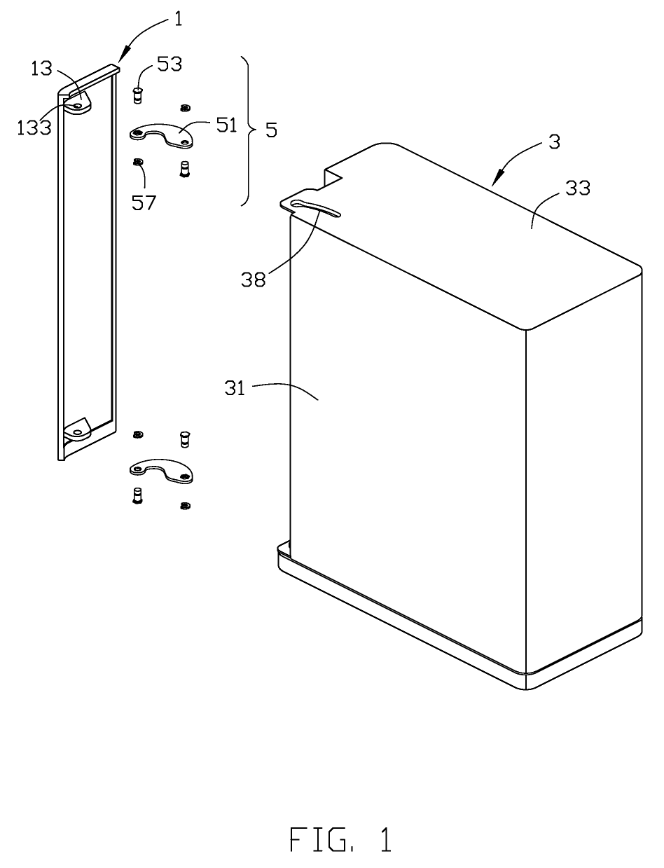

Referring to FIG. 1, a cover assembly is attached to an electronic device housing 3 for covering an I/O connector (not shown). The cover assembly includes a cover 1 and a pair of connecting arms 5 configured for connecting the cover 1 to the housing 3. The housing 3 has a side wall 31, a front wall and a pair of engaging walls 33 perpendicularly formed on opposite edges of the side wall 31. The engaging walls 33 include a top wall and a bottom wall. The I/O connector is formed on the front wall. A slot 38 is defined in each engaging wall 33 at a front side thereof adjacent to the side wall 31.

The cover 1 has a rectangular shape. A pair of ears 13 is formed on an inner surface of the cover 1. Each ear 13 has a pin hole 133 defined therein.

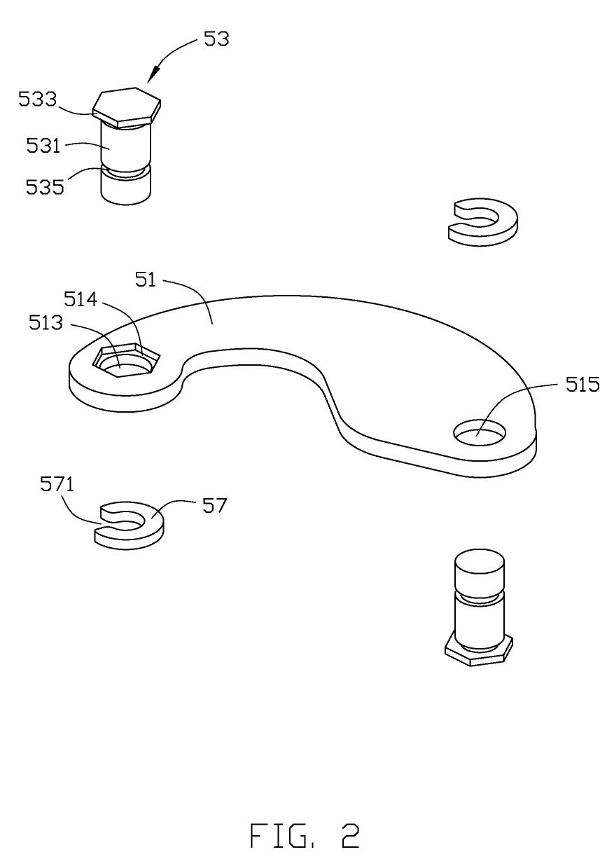

Referring also to FIG. 2, each connecting arm 50 has an arcuate structure. Each connecting arm 50 has a pin hole 513 defined at one end thereof and a pin hole 515 at the other end thereof for receiving two pins 53 respectively. Each pin 53 has a polygonal enlarged head portion 533 and a post 531. A circular slot is defined at a lower portion of the post 531. A resilient annular clip 57 with a cutout 571 is used for clipping into the circular slot 535. The pin holes 513 have a recess 514 for receiving the head portion 533 of the pin 53 so that the head portion 533 can be embedded into the connecting arm 51. An outer diameter of either the enlarged head 533 or the circular clip 57 is larger than a diameter of the pin holes 513, 514 or the pin holes 133 or the width of each slot 38.

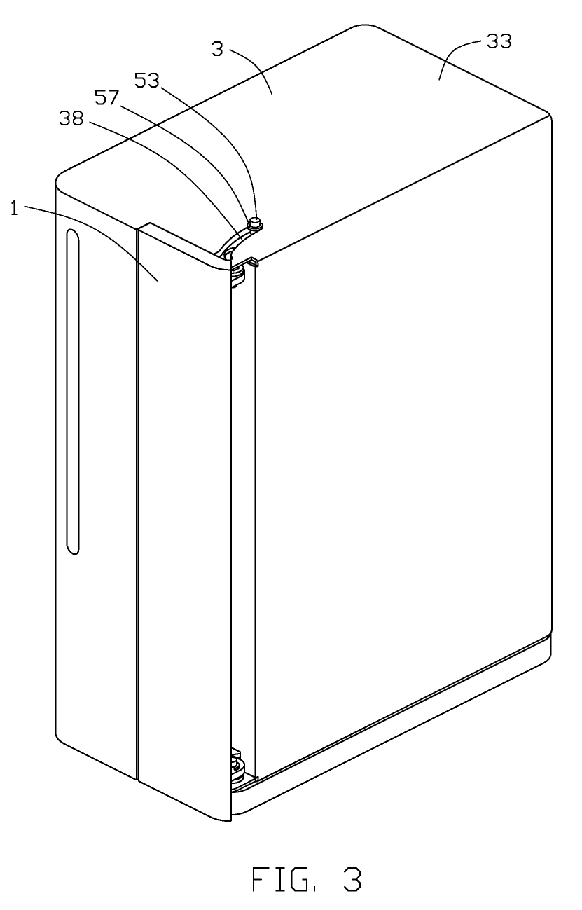

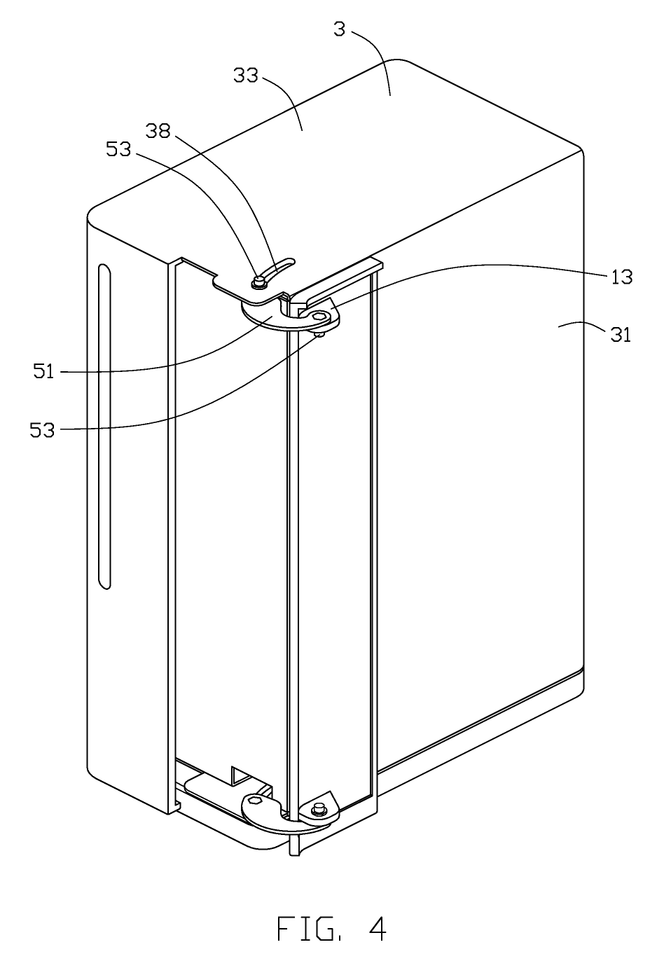

Referring also to FIG. 3 and FIG. 4, when assembling the cover assembly to the housing 3, one of the connecting arm 51 is beneath the engaging wall 33. The pin 53 is passed through the pin hole 515 and the slot 38 under the connecting arm 51 until the head portion 533 of the pin 53 is blocked by the connecting arm 51. The annular clip 57 is then clipped into the circular slot 535 so that the connecting arm 51 is pivotably attached to the engaging wall 33. Then one corresponding ear 13 of the cover 1 is placed beneath the connecting arm 51. Another pin 53 is passed through the pin hole 513 and the pin hole 133. The annular clip 57 is then clipped into the circular slot 535 so that the connecting arm 51 is pivotably attached to the cover 1. The other connecting arm 51 is attached to the housing 3 and the cover 1 symmetrically.

When opening the cover 1, the cover 1 is drawn from a closed position where the cover 1 covers on the I/O connector (not shown) to swing to a sideward to abut on the side wall 31. The pin 53 which received in the slot 38 is moved from one end to another end thereof. Then the cover 1 is totally opened.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A housing assembly comprising:
a housing comprising a front opening, a side wall, a top wall and a bottom wall positioning at opposite sides of the side wall, the top wall and bottom wall each having a slot defined therein;
a pair of connecting arms each having a first end slidably engaged in the slot, and an opposite second end; and
a cover pivotally connected to the second ends of the connecting arms, for covering the front opening of the housing.

2. The housing assembly as described in claim 1, wherein the cover has a first face and an opposite second face, and each of the connecting arms comprises a first pin at the first end thereof extending through and being slidable in the slot between a first position where the cover covers the front opening of the housing with the first face thereof facing toward an exterior of the housing, and a second position where the cover is unclosed, with the first face thereof abutting on the side wall of the housing.

3. The housing assembly as described in claim 2, wherein the first pins extend through the first ends of the connecting arms and the corresponding slots in the top and bottom wall for connecting the connecting arms to the respective top and bottom walls.

4. The housing assembly as described in claim 3, wherein each of the first pins has a head portion, and a circular slot defined at a distal portion thereof, and a resilient clip is engaged in the circular slot, the head portion and the clip having a size greater than a width of each of the slots in the top and bottom wall therebetween.

5. The housing assembly as described in claim 1, wherein a pair of ears is formed on the cover with the connecting arms coupled thereto via two pins.

6. The housing assembly as described in claim 5, wherein each of the connecting arms comprises a second pin, the second pins each having a head portion embedded in the second end of the connecting arm, and a circular slot defined at a distal portion, and a resilient clip engaged in the slot of each of the second pins.

7. A cover assembly for covering an I/O connector of a housing, the housing having a side wall, and a pair of engaging wall on opposite sides of the side wall, the cover assembly comprising:
a pair of connecting arms with each pivotally attached to each of the opposite engaging walls of the housing, the connecting arms pivotally about a first axis, the first axis perpendicular to the engaging walls and being movable thereon; and
a cover pivotally connected to the connecting arms, the cover being movable between a first position where the cover covering the I/O connector of the housing and a second position where the cover is unclosed and swung to abut on the side wall of the housing, wherein the first axis moves on the engaging walls while the cover is moved from the first position to the second position.

8. The cover assembly as described in claim 7, wherein a slot is defined in each engaging wall, and the first axis is movably along the slot.

9. The cover assembly as described in claim 8, wherein a first pin extends along the first axis through a first end of each connecting arm and the corresponding slot in the engaging wall for connecting each connecting arm to the engaging wall.

10. The cover assembly as described in claim 9, wherein each of the first pins has a head portion, and a circular slot defined at a distal portion thereof, and a resilient clip is engaged in the circular slot, the head portion and the clip having a size greater than a width of each of the slots in the engaging walls therebetween.

11. The cover assembly as described in claim 9, wherein each of the connecting arms comprises a second pin, the second pins each having a head portion embedded in a second end of the connecting arm, and a circular slot defined at a distal portion, and a resilient clip engaged in the slot of each of the second pins.
